(19) United States
(12) Patent Application Publication
(10) Pub. No.: US 2006/0279171 A1
(43) Pub. Date: Dec. 14, 2006

(54) Broadband, Nonreciprocal Network Element

(76) Inventors: Dwight D. Viehland, Blacksburg, VA (US); Jie-Fang Li, Blacksburg, VA (US); Mirza I. Bichurin, Novgorod (RU)

Correspondence Address: WHITHAM, CURTIS & CHRISTOFFERSON & COOK, P.C., 11491 SUNSET HILLS ROAD, SUITE 340, RESTON, VA, 20190, US

(21) Appl. No.: 11/421,856

(22) Filed: Jun. 2, 2006

Related U.S. Application Data
(60) Provisional application No. 60/689,096, filed on Jun. 10, 2005.

(51) Int. Cl. H01L 41/00

(52) U.S. Cl. 310/311

(57) ABSTRACT

A magneto-electric (ME) gyrator, which is a discrete, passive network element, comprises a laminated composite of piezoelectric and magnetostrictive layers. The ME gyrator approximately meets the following criteria:
V₁=−αI₂,
V₂=αI₁ (1a)
where V is voltage, I is current, and α is a conversion (or gyration) coefficient between voltage and current and non-reciprocity is manifested as a 180° phase shift between open and short circuit (I,V) conditions, and

$$\frac{α {c}_{0}}{\sqrt{{ɛ}_{eff} {μ}_{eff}}} \approx 1 \qquad ( 1 b )$$

where c₀ is the speed of light in vacuum, ε_{eff} is the effective relative dielectric constant, and μ_{eff} is the effective relative permeability.

### CROSS-REFERENCE TO RELATED APPLICATION

This application claims priority based provisional application Ser. No. 60/689,096 filed Jun. 10, 2005, the contents of which are incorporated herein by reference.

### GOVERNMENT LICENSE RIGHTS

The U.S. Government has a paid-up license in this invention and the right in limited circumstances to require the patent owner to license others on reasonable terms as provided for by the terms of Office of Naval Research Grant Numbers N000140210340, N000140210126 and N000140110761.

### BACKGROUND OF THE INVENTION

1. Field of the Invention

The present invention generally relates to electrical circuit elements and, more particularly, to a new broadband, non-reciprocal network element based on magneto-electric (ME) interaction.

2. Background Description

In 1948, Bernard D. H. Tellegen of Philips Research Laboratories, Eindhoven, published a seminal work on classic passive network elements Philips Research Reports 3, 81-101 (1948)), in which he theorized that an additional network element based on magneto-electric (ME) interaction should exist—which he designated a gyrator. An ideal gyrator would be unique with respect to the other known network elements, i.e., capacitance, resistance, inductance, and transformer, in that it would not comply with reciprocity, but rather would be nonreciprocal. Well-known microwave gyrators which work on the Faraday effect in ferrites use another operational principle. (See, for example, Hogan, C., Reviews of Modem Physics 25, 253 (1953).) In integrated circuit design, the primary use of a gyrator is to simulate an inductive element. Such a gyrator comprises an operational amplifier and an RC network. However, over the course of many years, the notion/hope of realizing a true passive network component with large gyration effects over a wide bandwidth has fallen into obscurity.

An ideal gyrator, illustrated in the equivalent circuit of FIG. 1, must meet two existence criteria, as originally given by Tellegen. First, it must obey the following set of algebraic equations:
V₁=−αI₂,
V₂=αI₁ (1a)
where V is voltage, I is current, and α is a conversion (or gyration) coefficient between voltage and current. Non-reciprocity is manifested as a 180° phase shift between open and short circuit (I,V) conditions. Second to qualify as an “ideal” gyrator, the I-V conversion coefficient must meet the following criteria:

$$\frac{α {c}_{0}}{\sqrt{{ɛ}_{eff} {μ}_{eff}}} \approx 1 \qquad ( 1 b )$$

where c₀ is the speed of light in vacuum, ε_{eff} is the effective relative dielectric constant, and μ_{eff} is the effective relative permeability. Only when conditions (1a) and (1b) are simultaneously satisfied can complete and total conversion between I and V, or vice-versa, occur.

### SUMMARY OF THE INVENTION

It is therefore an object of the present invention to provide the realization of a fifth discrete network component, which we designate the Tellegen gyrator.

According to the invention, there are provided laminated composites of piezoelectric and magnetostrictive layers which exhibit close to ideal characteristics of a gyrator; that is, these laminated composites approximate simultaneous satisfaction of conditions (1a) and (1b). More particularly, a preferred embodiment of the invention is implemented with a longitudinally-poled piezoelectric layer sandwiched between two longitudinally-magnetized Terfenol-D layers, i.e., a L-L mode configuration. Alternatively, laminates according to the teachings of the invention may be produced with transversely-poled piezoelectric and longitudinally magnetized Terfenol-D layers (or L-T mode), and a “push-pull” configuration that is a L-L mode whose piezoelectric layer is symmetrically poled. Alternatively, laminates according to the teachings of the invention may be produced with two, three, or even more (i.e., multi-layer) layers.

### BRIEF DESCRIPTION OF THE DRAWINGS

The foregoing and other objects, aspects and advantages will be better understood from the following detailed description of a preferred embodiment of the invention with reference to the drawings, in which:

FIG. 1 is a schematic circuit diagram representing an ideal gyrator;

FIG. 2 is a cross-sectional view of an L-L mode ME laminate according to the present invention;

FIG. 3 is a graph showing the phase difference between open and short circuit conditions for the L-L mode over a broad bandwidth from 1 to 7×10⁴ Hz;

FIG. 4 is a pictorial representation of an ME laminate in a “push-pull” configuration according to the invention;

FIG. 5 is a pictorial representation of an L-T mode ME laminate according to a further aspect of the invention;

FIG. 6 is a pictorial representation of a multi-layer ME laminate according to another aspect of the invention;

FIG. 7 is a pictorial representation of a bi-morph ME laminate according to yet another aspect of the invention; and

FIGS. 8A and 8B are, respectively, cross-sectional views of an unsymmetric and a symmetric unimorph ME laminate according to the invention.

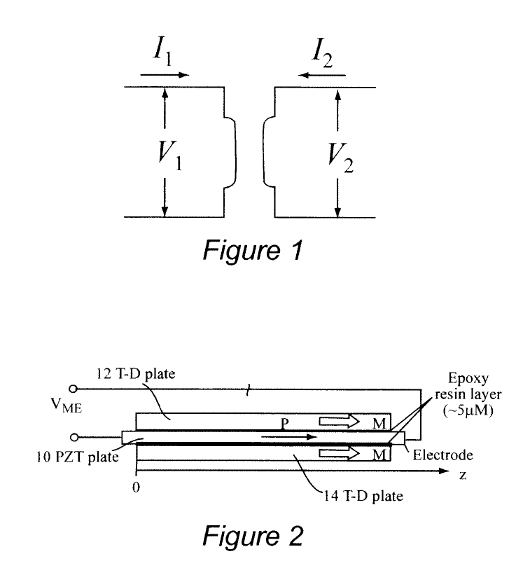

### DETAILED DESCRIPTION OF A PREFERRED EMBODIMENT OF THE INVENTION

We have discovered that laminated composites of piezoelectric and magnetostrictive layers come close to meeting the requirements (1a) and (1b) for ideal gyrators. We had previously developed such composites for studying magneto-electric (ME) effects, but had not yet realized the existence or importance of gyration. Here, we conclusively demonstrate the near-ideal gyrator capabilities of composites consisting of a Pb(Zr₁₋ₓTi₁₋ₓ)O₃(i.e, PZT) or (1-x)Pb(Mg_{1/3}Nb_{2/3})O₃−xPbTiO₃ (i.e., PMN-PT) piezoelectric layer laminated with magnetostrictive Terfenol-D layers. Terfenol-D has a composition of TbₓDy₁₋ₓFe_{y}, an alloy of rare earths Dysprosium and Terbium with Iron. It is a straight forward conclusion that laminates made of piezoelectric layers such as (1-x)Pb(Zn_{1/3}Nb_{2/3})O₃-xPbTiO₃ or other ferroelectric perovskites and other magnetostrictive layers such as Fe₁₋ₓGaₓ (i.e., Galfenol), magnetic alloys manufactured by Metglas, Inc. (Metglas Inc., Conway, S.C.), CoFe₂O₄ (CFO), NiFe₂O₄ (NFO) or other ferromagnetic ferrites would also have similar gyration characteristics.

In FIG. 2, we illustrate a ME laminate that has a longitudinally-poled piezoelectric layer or plate 10 sandwiched between two longitudinally-magnetized Terfenol-D layers or plates 12 and 14. We refer to this structure as an L-L configuration. The layers are laminated using an epoxy resin layer of approximately 5 μm thickness. The piezoelectric PZT layers were polycrystalline, whereas the PMN-PT ones were (001) oriented crystals. We could also use other oriented crystals, such as (111) or (110).

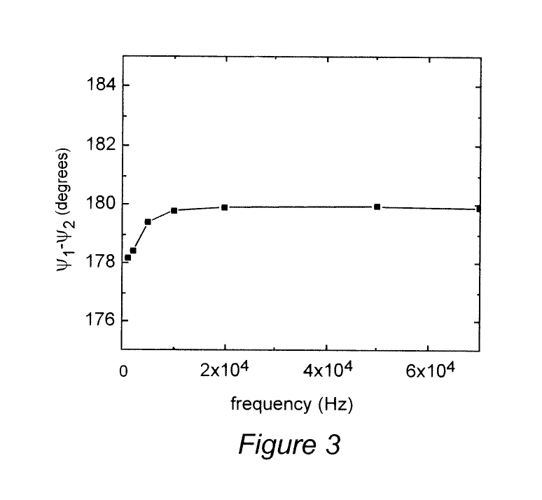

FIG. 3 shows the phase difference between one and short circuit conditions for the L-L mode over a broad bandwidth from 1 to 7×10⁴ Hz. Measurements were performed in a magnetically-shielded environment, and by using a dual lock-in amplifier method to calibrate the phase difference of the two signals. The results unambiguously demonstrate the existence of an 180° phase shift between I and V, which satisfies criteria (1a). This is the first report of such an 180° phase shift at low frequencies (<GHz), and it is distinctly different than the conventional 90° phase shift between I and V of Ohm's law. the results establish (I) the nonreciprocal nature of the couple, and (ii) the non-dissipative nature of the I-V conversion, i.e., current is not generated by a voltage drop.

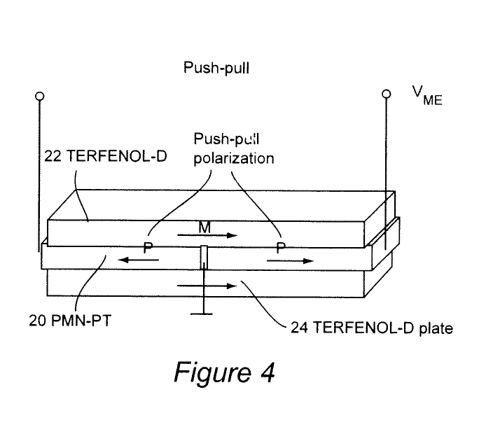

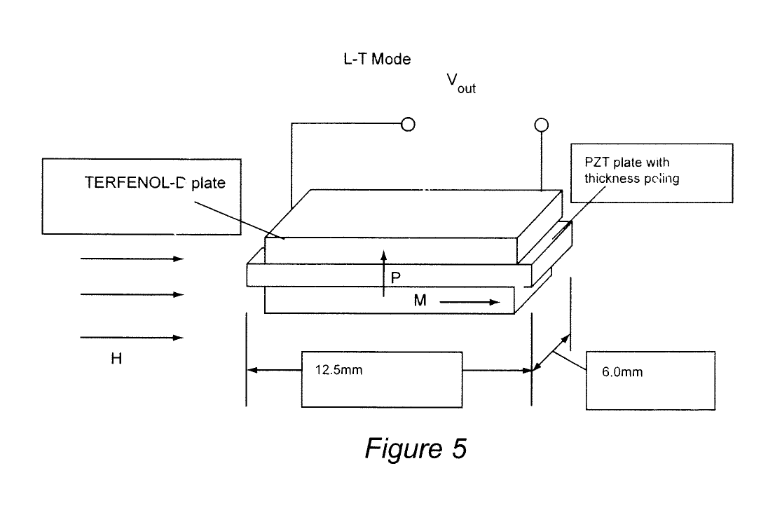

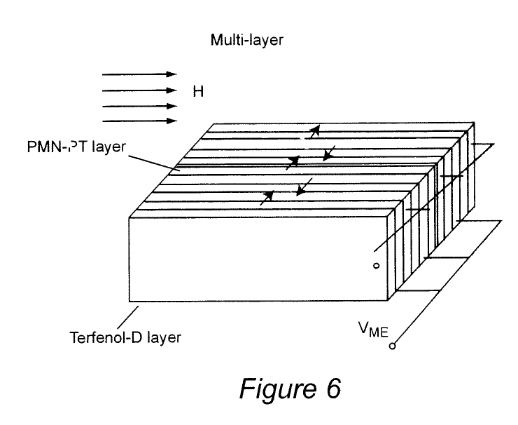

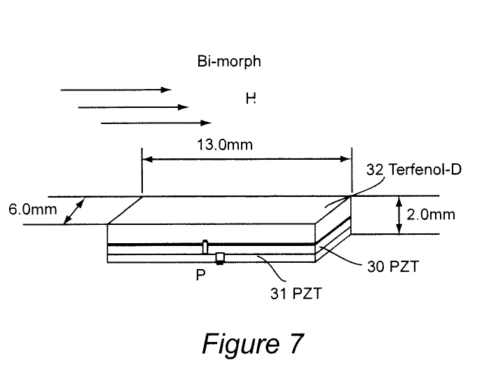

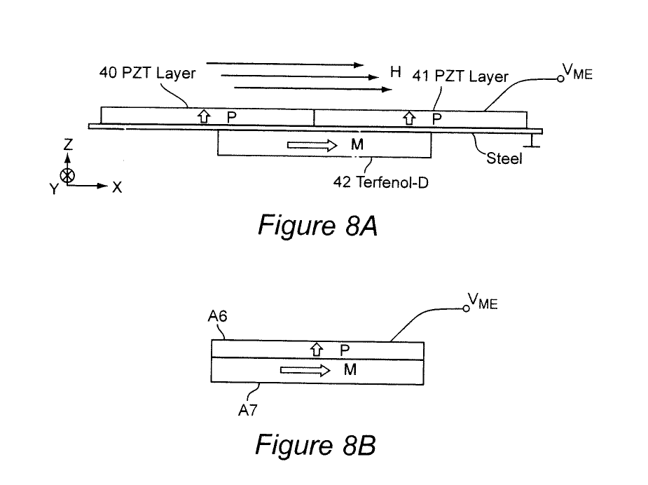

Other laminates may also be used to realize the gyrator of our invention. More particularly, a “push-pull” configuration that is a L-L mode whose piezoelectric layer is symmetrically poled is shown in FIG. 4. In this example, a PMN-PT piezoelectric plate 20, having a push-pull polarization, is laminated between two Terfenol-D plates 22 and 24. Laminates with transversely-poled piezoelectric and longitudinally magnetized Terfenol-D layers (which we refer to a L-T mode) can be realized as shown in FIG. 5. FIG. 6 shows a multi-layer structure of alternating Terfenol-D and PMN-PT layers. A bi-morph configuration of two PZT layers 30 and 31 and a Terfenol-D layer 32 is shown in FIG. 7. And in FIGS. 8A and 8B there are shown two unimorph configurations. The two PZT layers 40 and 41 in FIG. 8A are laminated in tandem with the Terfenol-D layer 42 to form an unsymmetric configuration, while a single PZT layer 46 is laminated to a Terfenol-D layer 47 in FIG. 8B to form a symmetric configuration.

Next, we turn our attention to the criteria of (1b), which is that for complete and total gyration between voltage and current. Table I shows the calculated values of this criteria,

$$\frac{α {c}_{0}}{\sqrt{{ɛ}_{eff} {μ}_{eff}}} ,$$

for the L-L, L-T and “push-pull” modes of (a) PMN-PT/Terfenol-D, and (b) PZT/Terfenol-D laminates.

TABLE I

| Composite Type | Mode (Thickness) | αₘₑ (s/m) | ε_{eff} | μ_{eff} | $\frac{α {c}_{0}}{\sqrt{{ɛ}_{eff} {μ}_{eff}}}$ |
|---|---|---|---|---|---|
| (a) PMN-PT/ | LL(1 mm) | 8.73 × 10⁻⁸ | 3917 | 5.73 | 0.1748 |
| Terfenol-D | LT(0.6 mm) | 5.09 × 10⁻⁸ | 2542 | 6.21 | 0.1215 |
| | push-pull | 9.92 × 10⁻⁸ | 3690 | 5.73 | 0.2046 |
| | (1 mm) | | | | |
| (b) PZT/ | LL (2 mm) | 1.79 × 10⁻⁸ | 1900 | 3.17 | 0.0692 |
| Terfenol-D | LT (2 mm) | 1.18 × 10⁻⁸ | 1620 | 3.21 | 0.0489 |
| | push-pull | 3.14 × 10⁻⁸ | 2486 | 3.17 | 0.1061 |
| | (2 mm) | | | | |

Table I shows the measured values for aₘₑ, ε_{eff} and μ_{eff} from which the criterion was estimated. The results given in Table I unambiguously demonstrate a significant gyration factor. The values of

$$\frac{α {c}_{0}}{\sqrt{{ɛ}_{eff} {μ}_{eff}}}$$

were about two to three times higher for the PMN-PT/Terfenol-D laminates, as compared to the same modes of PZT/Terfenol-D laminates. The highest value of about 0.2 (or 20% gyration) was obtained for the “push-pull” mode of PMN-PT/Terfenol-D. The results in Table I establish excellent gyration capabilities of our laminate composites down to low (near d.c.) frequencies.

Our ME laminate gyrator is a small, discrete, passive network element that offers revolutionary solutions to network and antenna design, over a broad frequency range. First, it has the unique property of transforming a short circuit into an open circuit, and in so doing converting inductance into capacitance (i.e., C=L/α²), or vice-versa. Accordingly, it offers new electrical components capable of tuning stray or mutual inductances in a circuit into purely capacitive ones. Second, as a new fundamental network element, it offers considerably improved and/or simplified solutions to many complex network problems. Third, because the phase angles can be changed by applied d.c. magnetic bias, it is possible to phase modulate signals over a broad bandwidth. in summary, we have discovered broadband, excellent gyration in ME laminate composites.

While the invention has been described in terms of a single preferred embodiment, those skilled in the art will recognize that the invention can be practiced with modification within the spirit and scope of the appended claims.

Having thus described our invention, what we claim as new and desire to secure by Letters Patent is as follows:

1. A magneto-electric (ME) gyrator which is a discrete, passive network element comprising a laminated composite of piezoelectric and magnetostrictive layers which approximately meets the following criteria:
V₁=−αI₂,
V₂=αI₁ (1a)
where V is voltage, I is current, and α is a conversion (or gyration) coefficient between voltage and current and non-reciprocity is manifested as a 180° phase shift between open and short circuit (I,V) conditions, and
$$\frac{α {c}_{0}}{\sqrt{{ɛ}_{eff} {μ}_{eff}}} \approx 1 \qquad ( 1 b )$$
where c₀ is the speed of light in vacuum, ε_{eff} is the effective relative dielectric constant, and μ_{eff} is the effective relative permeability.

2. The ME gyrator recited in claim 1, wherein the laminated composite comprises a longitudinally-poled piezoelectric layer sandwiched between two longitudinally-magnetized magnetostrictive layers.

3. The ME gyrator recited in claim 1, wherein the laminated composite comprises a piezoelectric plate having a push-pull polarization laminated between two magnetostrictive plates.

4. The ME gyrator recited in claim 1, wherein the laminated composite comprises a transversely-poled piezoelectric layer sandwiched between two longitudinally-magnetized magnetostrictive layers.

5. The ME gyrator recited in claim 1, wherein the laminated composite comprises a symmetrically-poled piezoelectric layer sandwiched between two longitudinally-magnetized magnetostrictive layers.

6. The ME gyrator recited in claim 1, wherein the piezoelectric layer is a Pb(Zr₁₋ₓTi₁₋ₓ)O₃ (PZT) layer having a polycrystalline structure.

7. The ME gyrator recited in claim 1, wherein the piezoelectric layer is a (1-x)Pb(Mg_{1/3}Nb_{2/3})O₃-xPbTiO₃ (PMN-PT) layer having a (001) oriented crystalline structure.

8. The ME gyrator recited in claim 1, wherein the piezoelectric layer is a (1-x)Pb(Mg_{1/3}Nb_{2/3})O₃-xPbTiO₃ (PMN-PT) layer having a (111) oriented crystalline structure.

9. The ME gyrator recited in claim 1, wherein the piezoelectric layer is a (1-x)Pb(Mg_{1/3}Nb_{2/3})O₃-xPbTiO₃ (PMN-PT) layer having a (110) oriented crystalline structure.

10. The ME gyrator recited in claim 1, wherein the magnetostrictive layer is TbₓDy₁₋ₓFe_{y} (Terfenol-D).

11. The ME gyrator recited in claim 1, wherein the magnetostrictive layer is Fe₁₋ₓGaₓ (Galfenol).

12. The ME gyrator recited in claim 1, wherein the laminate composite comprises a uni-morph structure consisting of one transversely-poled piezoelectric layer epoxied to one longitudinally magnetized magnetostrictive layer.

13. The ME gyrator recited in claim 1, wherein the laminate composite comprises a uni-morph structure of claim which operates in a low frequency bending mode.

14. The ME gyrator recited in claim 1, wherein piezoelectric and magnetostrictive layers are repeatedly stacked together in sequence to create a multi-layer laminate.

15. The ME gyrator recited in claim 1, wherein the piezoelectric layer is in general a perovskite ferroelectric, in ceramic or single crystal form.
